(19) United States
(12) Patent Application Publication
(10) Pub. No.: US 2009/0112395 A1
(43) Pub. Date: Apr. 30, 2009

(54) SYSTEM FOR DETECTING A BATTERY MALFUNCTION AND PERFORMING BATTERY MITIGATION FOR AN HEV

(75) Inventor: Danil V. Prokhorov, Canton, MI (US)

Correspondence Address: GIFFORD, KRASS, SPRINKLE,;ANDERSON & CITKOWSKI, P.C., P.O. BOX 7021, TROY, MI, 48007-7021, US

(73) Assignee: Toyota Motor Engineering & Manufacturing North America, Inc.., Erlanger, KY (US)

(21) Appl. No.: 11/931,564

(22) Filed: Oct. 31, 2007

(51) Int. Cl. G01R 31/36; G01M 15/00; G06F 17/00

(52) U.S. Cl. 701/33; 701/29

(57) ABSTRACT

A system for detecting malfunction of a battery in a hybrid electric vehicle and optionally mitigating the battery fault. A neural network forms a diagnostic circuit which receives signals representative of the required driveshaft torque and speed over a diagnostic period and a prior state of charge of the battery at the beginning of the diagnostic period as input signals. The diagnostic circuit generates an output signal representing a difference between an estimated state of charge of the battery at the end of the diagnostic period and the actual state of charge of the battery. In the event that the difference exceeds a predetermined threshold, a battery fault signal is generated. The battery fault signal may be employed to vary the engine speed and/or torque to perform battery fault mitigation by increasing the state of charge of the battery.

### BACKGROUND OF THE INVENTION

I. Field of the Invention

The present invention relates to a system utilizing a neural network for detecting malfunction of a battery in a hybrid electric vehicle (HEV) and performing battery mitigation in the event of a battery malfunction.

II. Description of Related Art

Hybrid electric vehicles (HEV) have enjoyed increasing popularity in recent times due to their increased fuel economy. Such HEVs include both a fuel-powered engine as well as an electric motor for propelling the HEV. An engine controller controls the relative activation of both the fuel engine as well as the electric motor to increase the overall fuel economy of the vehicle while maintaining vehicle performance.

The electric motors utilized in HEVs are relatively powerful, e.g. Oftentimes capable of generating 40 horsepower or more. As such, the REV requires a relatively large battery capable of producing high currents necessary to power the electric motor.

In the design of HEVs, it is important to strive for battery charge sustenance since large variations of the battery state of charge (SOC) can dramatically reduce the battery life. Indeed, large variations in the battery SOC may result in costly repairs or even necessitate replacement of the battery.

There have been no previously known acceptable methods or systems for monitoring the state of the battery for an HEV. As such, in the event of a faulty battery, the faulty operation of the battery and its inability to maintain an acceptable state of charge oftentimes went undetected until irreversible damage to the battery resulted.

### SUMMARY OF THE PRESENT INVENTION

The present invention provides a system for detecting battery malfunction in an HEV and battery mitigation in the event of a battery malfunction.

In brief, the present invention provides a diagnostic circuit in the form of a neural network which receives signals representative of the engine torque and current engine speed over a diagnostic period as well as a prior state of charge of the battery at the beginning of the diagnostic period. The diagnostic circuit neural network also receives the battery temperature at some time during the diagnostic period as an input signal.

Using conventional training techniques for neural networks, the neural network is trained to utilize the input signals to generate an output signal representative of the estimated state of charge for the battery at the end of the diagnostic period. The diagnostic circuit then compares the estimated state of charge of the battery as determined by the neural network with the actual state of charge of the battery at the end of the diagnostic period and produces an output signal from the diagnostic circuit representative of the difference between the estimated state of charge and the actual state of charge of the battery.

The difference between the actual and estimated state of charge of the battery is then compared by conventional means, such as a processor, to a predetermined threshold. A difference between the actual and estimated state of charge of the battery less than the predetermined threshold is indicative of normal operation of the battery. Conversely, a difference between the actual and estimated state of charge for the battery greater than the predetermined threshold is indicative of a faulty battery. In that event, the processor generates a battery fault output signal.

A faulty battery typically exhibits a lower state of charge than a normal operating battery. Consequently, in order to increase the state of charge of the battery in the event of a battery fault signal, the battery fault signal may be used as a signal to the engine controller to increase the torque and/or speed of the engine in an attempt to increase the state of charge for the battery and minimize battery damage. Preferably, the engine control unit also comprises a neural network and the battery fault output signal may be utilized to vary either the input or output signals from the neural network for the engine control unit to increase torque and/or speed.

### BRIEF DESCRIPTION OF THE DRAWING

A better understanding of the present invention will be had upon reference to the following detailed description when read in conjunction with the accompanying drawing, wherein like reference characters refer to like parts throughout the several views, and in which:

FIG. 1 is an exemplary graph illustrating the state of charge of a battery for an HEV as a function of time;

FIG. 2 is a block diagrammatic view illustrating a preferred embodiment of the present invention;

FIG. 3 is a flowchart illustrating the operation of the present invention; and

FIG. 4 is similar to FIG. 3, but illustrating a modification thereof.

### DETAILED DESCRIPTION OF PREFERRED EMBODIMENTS OF THE PRESENT INVENTION

With reference first to FIG. 1, an exemplary graph 20 of the state of charge of a battery for an HEV is there shown as a function of time. The state of charge will vary between zero, indicative of a fully discharged battery, and one, indicative of a fully charged battery. The actual state of charge of the battery 20, furthermore, varies as a function of the demands of the electric motor utilized in the HEV as well as other electrical systems in the HEV. A high electrical demand reduces the battery state of charge and vice versa.

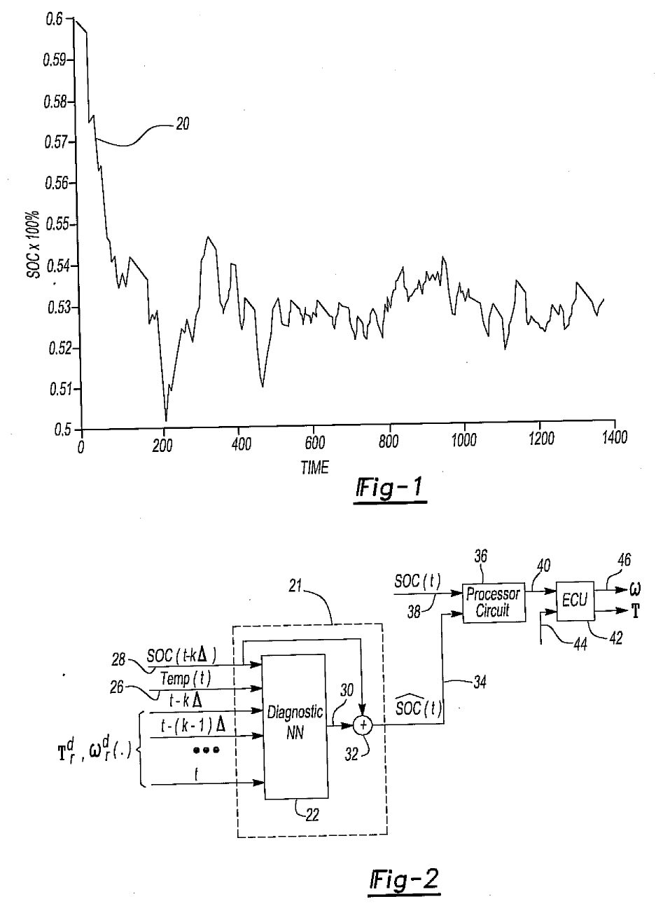

With reference now to FIG. 2, a diagnostic circuit 21 having a neural network 22 forms a circuit for diagnosing a battery fault, i.e. a battery with lower than expected performance. The diagnostic neural network 22 receives at least one, and preferably several values of the required driveshaft torque T^{d}ᵣ as well as at least one and preferably several values of the required driveshaft speed ω^{d}ᵣ as input signals. For example, the torque T^{d}ᵣ and speed ω^{d}ᵣ may be determined through conventional sensors over a predetermined diagnostic time period, e.g. nine seconds, for each time increment Δt for a number of k steps during the diagnostic period. At least one, and preferably several of the measured values for the torque T^{d}ᵣ and speed ω^{d}ᵣ during the diagnostic period then form the input signals to the diagnostic neural network 22.

The diagnostic neural network 22 also receives a signal on input line 26 representative of the temperature of the battery as determined from a battery temperature sensor. As is well known, the temperature of the battery increases during heavy current draws. However, the rate of change of the temperature of the battery is very slow as contrasted with the rate of change of the torque T^{d}ᵣ and speed ω^{d}ᵣ. Consequently, a single temperature signal at any time during the diagnostic period to the diagnostic neural network 22 is sufficient for the entire diagnostic period.

The diagnostic neural network 22 also receives a signal on line 28 representative of the state of charge of the battery at the beginning of the diagnostic period, e.g. at time=t−kΔt where k represents the number of measuring steps for the torque and speed inputs for the neural network 22 during the diagnostic period while At equals the time increment between each step. For example, for the previously mentioned example of nine steps of one second each, the state of charge of the battery is provided as an input signal to the diagnostic neural network 22 at the beginning of the diagnostic period while the torque T^{d}ᵣ and speed ω^{d}ᵣ input signals are provided to the diagnostic network 22 not only during the first step, but in the succeeding eight steps so that the entire diagnostic period extends for nine seconds.

The diagnostic neural network 22 is trained using conventional training methods for neural networks to provide an output signal on its output 30 representative of the change in the state of charge from the initiation of the diagnostic period and to the conclusion of the diagnostic period at time t.

The output 30 from the diagnostic network 22 is coupled to a summing junction 32 which also receives an input signal coupled to line 28 representative of the state of charge of the battery at the initiation of the diagnostic period. An output 34 from the diagnostic circuit 21 represents an estimated state of charge for the current time t, i.e. the time at the end of the diagnostic period. The output signal 32 from the diagnostic circuit 21 is then coupled as an input signal to a processor circuit 36 which compares the estimated state of charge for the battery at the current time [symbol] with the actual state of charge of the battery at the current time SOC(t) on input line 38. In the event that the estimated state of charge [symbol] on line 34 varies from the actual state of charge SOC(t) of the battery on input line 38 by an amount greater than a predetermined threshold, the processor circuit 36 generates a battery fault signal on its output 40.

The battery fault output signal on line 40 from the processor circuit 36, which is preferably microprocessor based, may be used for a variety of different purposes, such as alerting the operator of the HEV of the faulty battery condition as well as setting a maintenance flag in the processor circuit 36 that may be examined during a subsequent vehicle maintenance check. However, the faulty battery output on line 40 may also be used to mitigate any possible damage that may be caused to the battery.

More specifically, the battery fault output on line 40 may be used as an input to an engine control unit (ECU) 42, which preferably includes a neural network, used to control the operation of the fuel-powered engine for the HEV. The ECU 42, in the conventional fashion, receives a plurality of inputs 44 representative of engine or vehicle operating parameters of one sort or the other. The ECU then generates signals on its outputs 46 to control the speed and/or torque of the fuel operated engine.

For example, in the event that the state of charge of the battery falls below the estimated state of charge of the vehicle by more than the predetermined threshold, the ECU 47, in response to the processor output on line 40, may increase the engine speed and/or torque in an effort to increase the state of charge of the battery.

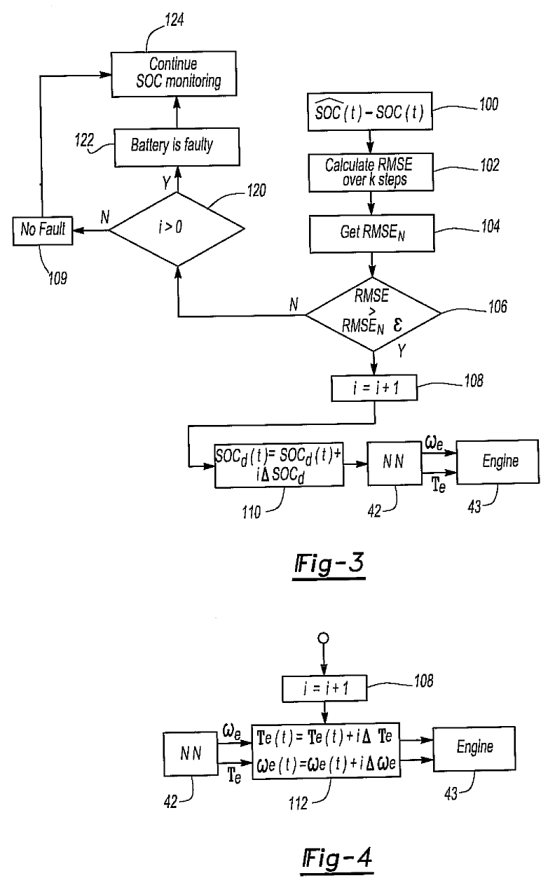

With reference now to FIG. 3, a flowchart illustrating the operation of the present invention is shown where the ECU 42 comprises a neural network. At step 100, the difference between the actual state of charge SOC(t) and the estimated state of charge [symbol] at time t is determined. Step 100 then proceeds to step 102. At step 102, the root mean square error (RMSE), or another suitable error measure, between the estimated and actual state of charge of the battery is calculated over k time steps. Step 102 then proceeds to step 104.

At step 104, the processor retrieves the RMSE_{N} value for a normal battery. Any conventional means may be used to retrieve the RMSE_{N}, such as from a lookup table. Step 104 then proceeds to step 106.

At step 106, the RMSE calculated at step 102 is compared with RMSE_{N} retrieved at step 104 plus a where a represents a threshold difference between an acceptable value for the RMSE of the battery and an unacceptable value. If the RMSE value determined at step 102 is less than the RMSE_{N} value for a normal battery plus the threshold amount ε, indicative of normal battery operation, step 106 branches to step 120 where the value of a counter i is examined. If i is greater than zero, indicative of a battery fault, step 120 branches to step 122 where a battery fault flag is set and then to step 124 where the battery monitoring routine continues. Conversely; if i is equal to zero, indicative of no battery fault previously detected, step 120 instead branches to step 109 where a no fault flag is set and then to step 124 where the battery monitoring continues.

Conversely, if the RMSE value determined at step 102 is less than RMSE plus the threshold amount, step 106 instead branches to step 108 where counter i is incremented. This counter i is then utilized by the ECU 42 to alter the operation of the fuel engine in an effort to increase the state of charge of the battery. This can be done in one of two ways.

First, after the counter i has been incremented at step 108, the counter i may be used to increase the input representing the desired state of charge to the ECU 42. Thus, as shown in FIG. 3, step 108 proceeds to step 110 where the desired state of charge SOC_{d}(t) provided as an input to the ECU 42 is incremented by an amount iΔSOC_{d} where ΔSOC_{d} represents a small change in the desired state of charge for the battery. Consequently, the input to the neural network which forms a part of the ECU 42 may be varied to vary the outputs from the ECU 42 to control the fuel engine 43. Other inputs to the NN 42 may include the current state of charge SOC(t), the engine fuel rate, etc., necessary to operate the NN in a form of feedback controller for the engine.

Alternatively, with reference now to FIG. 4, in the event of a detection of a battery fault, the outputs, rather than input, to the ECU 42 may be altered in order to vary the operation of the fuel engine 43 in an attempt to increase the state of charge of the battery. More specifically, two of the outputs from the ECU 42 represent the desired engine torque T and speed ω. At step 112 the torque and speed outputs from the ECU 42 are modified by incrementing the torque output by an amount iΔTₑ and, similarly, incrementing the speed by the amount iΔωₑ where ΔTₑ represents a small torque change and Δωₑ represents a small speed change. These incremented amounts for the speed ωₑ and torque Tₑ are then provided to control the engine 43. In most situations, increasing the torque or speed of the engine 43 will increase the state of charge of the battery.

If the battery is determined as having a fault (block 122), then the driver is advised to go to a repair shop. A repair shop technician then replaces or repairs the faulty battery and resets the counter i to zero.

From the foregoing, it can be seen that the present invention provides a unique system which utilizes a neural network to monitor the status or state of charge of the battery for an HEV. In the event that the state of charge falls below acceptable thresholds, the system further optionally takes steps to mitigate any damage that may occur to the battery by increasing the speed or torque of the fuel engine which likewise increases the state of charge of the battery.

Having described my invention, however, many modifications thereto will become apparent to those skilled in the art to which it pertains without deviation from the spirit of the invention as defined by the scope of the appended claims.

I claim:

1. A system for detecting malfunction of a battery in a hybrid electric vehicle having an electric motor and a fuel engine comprising:
a diagnostic circuit which receives signals representative of required driveshaft torque and speed over a diagnostic time period and a state of charge of the battery at the beginning of the diagnostic period as input signals and generates an output signal at the end of the diagnostic period representing a difference between an estimated state of charge of the battery at the end of the diagnostic period and the actual current state of charge of the battery at the end of the diagnostic period, and
means for generating a battery fault signal whenever said difference exceeds a predetermined threshold.

2. The invention as defined in claim 1 wherein said diagnostic circuit comprises a neural network.

3. The invention as defined in claim 1 wherein said generating means comprises a programmed processor.

4. The invention as defined in claim 1 wherein said circuit further receives an input signal representative of a current temperature of the battery.

5. The invention as defined in claim 1 and comprising a mitigation circuit responsive to said battery fault signal to adjust at least one of torque and speed of the fuel engine.

6. The invention as defined in claim 5 wherein said mitigation circuit comprises a neural network.

7. The invention as defined in claim 6 wherein said mitigation circuit varies at least one input to the mitigation circuit neural network in response to said battery fault signal.

8. The invention as defined in clam 6 wherein said mitigation circuit varies at least one output from the mitigation circuit neural network in response to said battery fault signal.

9. A system for detecting malfunction of a battery in a hybrid electric vehicle having a fuel engine and thereafter providing battery mitigation comprising:
a diagnostic circuit which receives signals representative of required driveshaft torque and speed over a diagnostic time period and a state of charge of the battery at the beginning of the diagnostic period as input signals and generates an output signal at the end of the diagnostic period representing a difference between an estimated state of charge of the battery at the end of the diagnostic period and the actual current state of charge of the battery at the end of the diagnostic period,
means for generating a battery fault signal whenever said difference exceeds a predetermined threshold, and
a mitigation circuit responsive to said battery fault signal to adjust at least one of the control signals to the fuel engine.

10. The invention as defined in claim 9 wherein said diagnostic circuit comprises a neural network.

11. The invention as defined in claim 9 wherein said generating means comprises a programmed processor.

12. The invention as defined in claim 9 wherein said circuit farther receives an input signal representative of a current temperature of the battery.

13. The invention as defined in claim 12 wherein said mitigation circuit comprises a neural network.

14. The invention as defined in claim 13 wherein said mitigation circuit varies at least one input to the mitigation circuit neural network in response to said battery fault signal.

15. The invention as defined in claim 13 wherein said mitigation circuit varies at least one output from the mitigation circuit neural network in response to said battery fault signal.
